(19) United States
(12) Patent Application Publication
(10) Pub. No.: US 2026/0086142 A1
(43) Pub. Date: Mar. 26, 2026

(54) METHOD AND APPARATUS OF PREDICTING ENDURANCE OF CHIP, MEDIUM, AND ELECTRONIC DEVICE

(71) Applicant: INSTITUTE OF MICROELECTRONICS, CHINESE ACADEMY OF SCIENCES, Beijing (CN)

(72) Inventors: Xiaoxin XU, Beijing (CN); Xu ZHENG, Beijing (CN); Lizhou WU, Beijing (CN); Xiaoyong XUE, Beijing (CN); Wan PANG, Beijing (CN)

(21) Appl. No.: 19/110,247

(22) PCT Filed: May 17, 2023
(86) PCT No.: PCT/CN2023/094675

§ 371 Date: Mar. 10, 2025

(30) Foreign Application Priority Data
Feb. 8, 2023 (CN) 202310140488.7

(51) Int. Cl. G01R 31/28

(52) U.S. Cl. CPC G01R 31/2837; G01R 31/2846

(57) ABSTRACT

The present disclosure relates to a field of semiconductor technology, and in particular to a method and apparatus of predicting an endurance of a chip, a computer-readable medium, and an electronic device. The method includes: building a dataset according to endurance test data of a target chip, where the dataset includes a training set and a test set; acquiring a machine learning model, and training the machine learning model through the training set; and predicting an endurance of the target chip through the machine learning model.

### CROSS REFERENCE TO RELATED APPLICATION

This application is a Section 371 National Stage Application of International Application No. PCT/CN2023/094675, filed on May 17, 2023, entitled “METHOD AND APPARATUS OF PREDICTING ENDURANCE OF CHIP, MEDIUM, AND ELECTRONIC DEVICE”, this application claims priority to Chinese Patent Application No. 202310140488.7, filed on Feb. 8, 2023, the entire content of which is incorporated herein in its entirety by reference.

### TECHNICAL FIELD

The present disclosure relates to a field of a semiconductor technology, and in particular, to a method and apparatus of predicting an endurance of a chip, a computer-readable medium, and an electronic device.

### BACKGROUND

A non-volatile memory chip has advantages of fast access time, a low power consumption, a good compatibility with an advanced process node, etc., and is a promising next-generation embedded memory technology in the Internet of Things and an artificial intelligence application. However, compared with a flash memory, a reliability of the non-volatile memory chip is still a problem. Endurance and retention are the two most concerned reliabilities of the non-volatile memory chip. Due to a limitation of a test period and an evaluation method, a research on the endurance is mostly focused on a physical model at a chip level. However, due to an inevitable noise and defect in a system and process manufacturing, an application of a memory chip requires a data-driven reliability model based on statistical data. With a popularization of machine learning and a neural network, they are widely used in a reliability research of a semiconductor memory chip. It is very important for an improvement of a reliability and yield of a memory to implement repair measures according to a prediction result. However, due to a series of random factors provided in an endurance test of a resistive random access memory chip, a prediction model has not been established for predicting various states of an endurance of the non-volatile memory chip.

Based on this, those ordinary skilled in the art urgently need a method of predicting an endurance of a chip, which may predict various possible states of the non-volatile memory chip in a certain prediction span in the future, so as to perform a repairment in advance in a targeted manner, and finally improve a service life of the non-volatile memory chip.

### SUMMARY

Embodiments of the present disclosure provide a method and apparatus of predicting an endurance of a chip, a computer-readable medium, and an electronic device, so as to predict a state of a memory cell of a non-volatile memory chip in a certain prediction span in the future, so as to perform a repairment in advance in a targeted manner, and finally improve a service life of the non-volatile memory chip.

According to an aspect of the embodiments of the present disclosure, there is provided a method of predicting an endurance of a chip, including: building a dataset according to endurance test data of a target chip, where the dataset includes a training set and a test set; acquiring a machine learning model, and training the machine learning model through the training set; and predicting an endurance of the target chip through the machine learning model.

According to another aspect of the embodiments of the present disclosure, there is provided an apparatus of predicting an endurance of a chip, including: a building unit configured to build a dataset according to endurance test data of a target chip, where the dataset includes a training set and a test set; an acquisition unit configured to acquire a machine learning model and train the machine learning model through the training set; and a prediction unit configured to predict an endurance of the target chip through the machine learning model; where the machine learning model includes a state transition matrix, an observed-state probability matrix and a hidden-state initial probability distribution, the state transition matrix is configured to characterize a probability that the target chip jumps to each hidden state when the target chip is in a certain hidden state, and the observed-state probability matrix is configured to characterize a probability of an occurrence of each observed state when the target chip is in a certain hidden state.

According to another aspect of the embodiments of the present disclosure, there is provided a computer-readable storage medium, where the computer-readable storage medium stores at least one program code, and the at least one program code is loaded and executed by a processor to implement steps of the method of predicting an endurance of a chip.

According to another aspect of the embodiments of the present disclosure, there is provided an electronic device, including a memory and a processor, where the memory stores a computer program which, when executed by the processor, causes the processor to perform steps of the method of predicting an endurance of a chip.

### BRIEF DESCRIPTION OF THE DRAWINGS

FIG. 1 shows a flowchart of a method of predicting an endurance of a chip according to some embodiments of the present disclosure.

FIG. 2 shows a flowchart of acquiring endurance test data of a target chip for at least one working period according to some embodiments of the present disclosure.

FIG. 3 shows a schematic diagram of building a training set according to some embodiments of the present disclosure.

FIG. 4 shows a block diagram of model training according to some embodiments of the present disclosure.

FIG. 5 shows a block diagram of model prediction according to some embodiments of the present disclosure.

FIG. 6 shows a schematic diagram of a model training result according to some embodiments of the present disclosure.

FIG. 7 shows a schematic diagram of a model prediction result of some embodiments of the present disclosure.

FIG. 8 shows a schematic diagram of a step-by-step repair algorithm according to some embodiments of the present disclosure.

FIG. 9 shows a schematic diagram of an optimization result of a step-by-step repair algorithm according to some embodiments of the present disclosure.

FIG. 10 shows a block diagram of an apparatus of predicting an endurance of a chip according to some embodiments of the present disclosure.

FIG. 11 shows a schematic structural diagram of a computer system of an electronic device according to some embodiments of the present disclosure.

### DETAILED DESCRIPTION OF EMBODIMENTS

Exemplary embodiments will now be described more fully with reference to accompanying drawings. However, the exemplary embodiments may be implemented in various forms and should not be construed as limited to examples set forth herein. On the contrary, these embodiments are provided, so that the present disclosure will be more thorough and complete, and the concept of the exemplary embodiments will be fully conveyed to those ordinary skilled in the art.

In addition, the described features, structures, or features may be combined by any suitable method in one or more embodiments. In the following descriptions, many specific details are provided to provide a thorough understanding for the embodiments of the present disclosure. However, those ordinary skilled in the art may realize that the technical solutions of the present disclosure may be practiced without one or more of the specific details, or other methods, components, apparatuses, steps, etc. may be adopted. In other cases, well-known methods, apparatuses, implementations or operations are not shown or described in detail to avoid obscuring various aspects of the present disclosure.

Block diagrams shown in the accompanying drawings are only functional entities and do not necessarily correspond to physically independent entities. That is, these functional entities may be implemented in a form of software, or in one or more hardware modules or integrated circuits, or in different networks and/or processor apparatuses and/or microcontroller apparatuses.

Flowcharts shown in the accompanying drawings are only illustrative, and they do not necessarily include all the contents and operations/steps, and are not necessarily executed in the described order. For example, some operations/steps may be decomposed, while some operations/steps may be combined or partially combined. Therefore, the actual execution order may change according to actual situations.

It should be noted that “multiple” mentioned herein means two or more. “And/or” is used to describe an association relationship of related objects, indicating that there may be three relationships. For example, A and/or B may indicate that A exists alone, A and B exist at the same time, and B exists alone. A character “/” generally indicates an “OR” relationship of context objects.

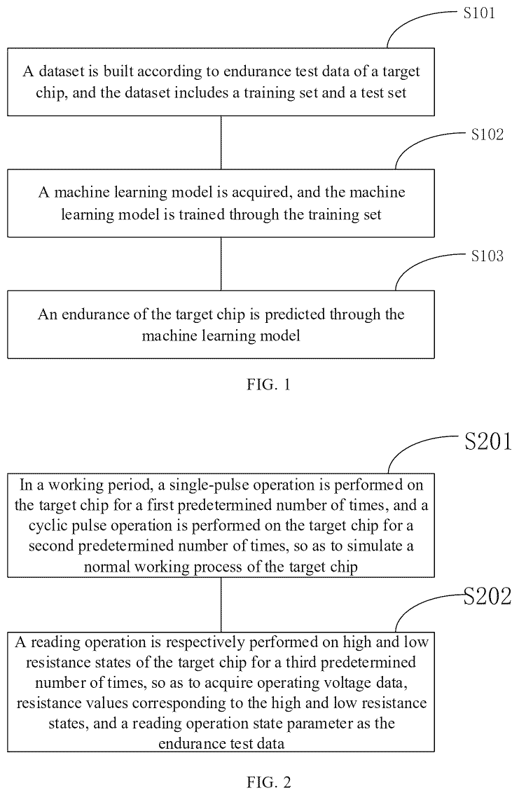

Please refer to FIG. 1. FIG. 1 shows a flowchart of a method of predicting an endurance of a chip according to some embodiments of the present disclosure. The method of predicting an endurance of a chip at least includes steps S101 to S103.

In step S101, a dataset is built according to endurance test data of a target chip, and the dataset includes a training set and a test set.

In step S102, a machine learning model is acquired, and the machine learning model is trained through the training set.

In step S103, an endurance of the target chip is predicted through the machine learning model.

In some embodiments of the present disclosure, the training set may account for 65% of the entire dataset, and the test set may account for 35% of the entire dataset.

In other embodiments of the present disclosure, the dataset is built according to the endurance test data of the target chip, and the dataset includes the training set and the test set, then the machine learning model is trained through the training set, and finally the endurance of the target chip is predicted through the machine learning model.

In other embodiments of the present disclosure, a state of a memory cell of a non-volatile memory chip in a certain prediction span in the future may be predicted by training the machine learning model and then predicting the endurance through the machine learning model, so as to perform a repairment in advance in a targeted manner, and finally improve a service life of the non-volatile memory chip.

In other embodiments of the present disclosure, the state of the memory cell of the non-volatile memory chip may include four situations: set fail, reset fail, both success and both fail.

In other embodiments of the present disclosure, the method of building a dataset according to endurance test data of a target chip may include: acquiring the endurance test data of the target chip for at least one working period, and building the dataset based on the endurance test data of each period.

Please refer to FIG. 2. FIG. 2 shows a flowchart of acquiring endurance test data of a target chip for at least one working period according to some embodiments of the present disclosure. The method of acquiring the endurance test data of the target chip for at least one working period may include steps S201 to S202.

In step S201, in a working period, a single-pulse operation is performed on the target chip for a first predetermined number of times, and then a cyclic pulse operation is performed on the target chip for a second predetermined number of times, so as to simulate a normal working process of the target chip.

In step S202, a reading operation is respectively performed on high and low resistance states of the target chip for a third predetermined number of times, so as to acquire operating voltage data, resistance values corresponding to the high and low resistance states, and a reading operation state parameter as the endurance test data.

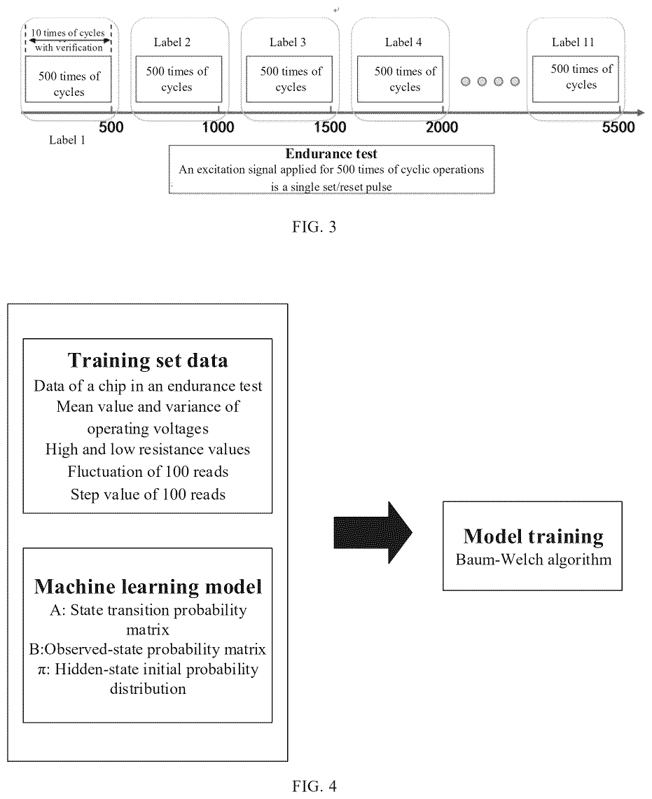

For example, please refer to FIG. 3. FIG. 3 shows a schematic diagram of building a training set according to some embodiments of the present disclosure. 500 times of cycles may be defined as a label, which represents a working period. In order to speed up a test, the 500 times of cycles are taken as the first predetermined number of times, and a single-pulse set/reset operation is used in the cycle without performing the reading operation. After each label test is finished, the state of the non-volatile memory chip may be verified by applying the pulse for 10 times of cycles, that is, the second predetermined number of times, and the normal working process of the non-volatile memory chip may be simulated through the above-mentioned operations. After 10 times of operations with verification, continuous reading operations may be performed on the high and low resistance states of the chip for 100 times respectively, that is, the third predetermined number of times, that is, 100read, and a reading voltage is 0.3 V. At this time, the operating voltage data, the resistance values corresponding to the high and low resistance states, and the reading operation state parameter may be acquired as endurance test data.

In some embodiments of the present disclosure, since different conductive filament shapes may lead to different failure modes, and the continuous reading operations under different conductive filament shapes may have different fluctuations, the above-mentioned reading operation state parameter may include a fluctuation of 100 reads and a step value of 100 reads.

Next, please refer to FIG. 4. FIG. 4 shows a block diagram of model training according to some embodiments of the present disclosure. The method of acquiring the machine learning model may include: acquiring the machine learning model, where the machine learning model including a state transition matrix, an observed-state probability matrix and a hidden-state initial probability distribution. The state transition matrix is configured to characterize a probability that the target chip jumps to each hidden state when the target chip is in a certain hidden state, and the observed state probability matrix is configured to characterize a probability of an occurrence of each observed state when the target chip is in a certain hidden state.

In other embodiments of the present disclosure, the method of training the machine learning model through the training set may include: determining the operating voltage data in the training set, the resistance values corresponding to the high and low resistance states, and the reading operation state parameter in the training set as the endurance test data as an input, training the machine learning model by using a Baum-Welch algorithm, so as to determine the state transition matrix, the observed-state probability matrix, and the hidden-state initial probability distribution.

For example, in order to predict different failure modes of the endurance of the chip, it is necessary to train a parameter of the machine learning model. The machine learning model may be a Hidden Markov Model (HMM). Firstly, a discrete observed state acquired by T labels may be defined as an observation sequence O, that is, O={O0, O1, . . . . OT}. The observed state OT of each label includes a resistance value after a cyclic operation in the current period and a corresponding fluctuation of 100read. Secondly, the Baum-Welch algorithm is used, and the observation sequence O is taken as an input. By training the machine learning model, a corresponding machine learning model λ=(a, B, π) is finally acquired. A matrix A is the state transition matrix, a matrix B is the observed-state probability matrix, and π is the hidden-state initial probability distribution.

In some embodiments of the present disclosure, the state transition matrix A may be as follows.

$$A = {[ {a}_{ij} ]}_{N \times M}$$

$${a}_{ij} = P ( {i}_{t + 1} = {q}_{j} \vert {i}_{t} = {q}_{i} ) , i = 1 , 2 , … N ; j = 1 , 2 , … , N$$

The above-mentioned equations may be used to represent a probability of transitioning to a state qⱼ at time t+1 under a condition of being in state qᵢ at time t. A physical meaning of A is: assuming that the chip is in a hidden state (qᵢ) at time t, a probability that the chip may jump to each hidden state (qᵢ) at the time t+1.

In other embodiments of the present disclosure, the observed-state probability matrix B may be as follows.

$$B = {[ {b}_{j} ( k ) ]}_{N \times M}$$

$${b}_{j} ( k ) = P ( {o}_{t} = {v}_{k} \vert {i}_{t} = {q}_{j} ) , k = 1 , 2 , … , M ; j = 1 , 2 , … N$$

The above-mentioned equations may be used to represent a probability of generating an observed vₖ state at time t under a condition of being in the state qⱼ. A physical meaning of B is: at time t, when the chip is in a hidden state (qᵢ), a probability of an occurrence of each observed state (V_{K}) (V_{K}: a resistance value of the chip at the time t and a corresponding 100read fluctuation).

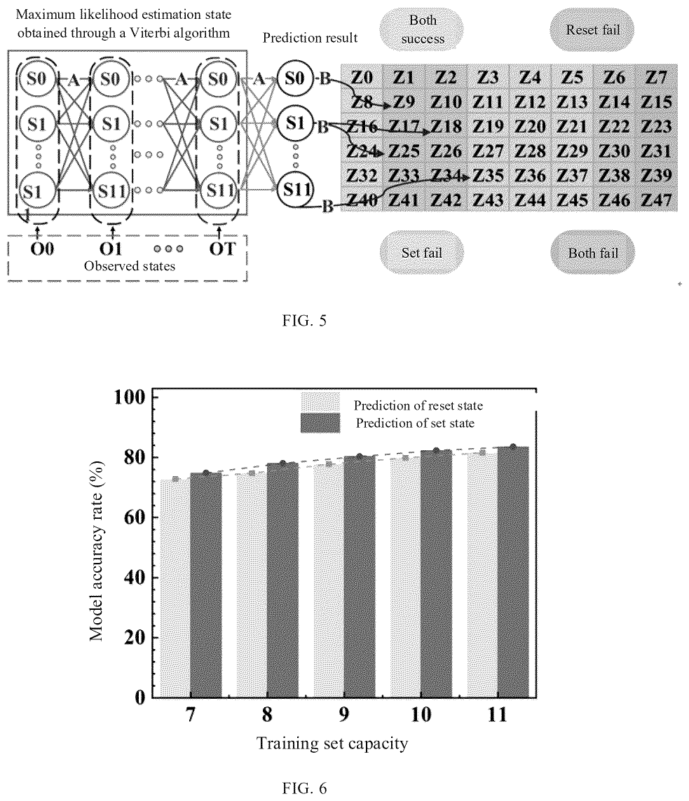

Next, please refer to FIG. 5. FIG. 5 shows a block diagram of model prediction according to some embodiments of the present disclosure. During the prediction, it may be assumed that the chip has 12 hidden states. The trained machine learning model and the observation sequence O={O0, O1, . . . . OT} are used as inputs of a Viterbi algorithm. Finally, the maximum likelihood hidden state of 12 hidden states in a period T is output. The maximum likelihood hidden state is iterated with the matrix A to obtain a transition probability of each hidden state in a target period (a period T+1). Then, the transition probability of each hidden state in the period T+1 is multiplied with the matrix B to obtain the probability of the occurrence of each observed state, and the state with the greatest probability is selected to correspond to an observed state space, so as to obtain which of the four states a unit may be in during the period T+1.

In the above-mentioned embodiments, the observed state space may be composed of two dimensions: the fluctuation of 100 reads and the resistance value after the cyclic operation. Fluctuation parameters include six categories: a variance of 100 Reset reads and a variance of 100 Set reads; a variance of 100 Reset writings and a variance of 100 Set writings; a step quantity of 100 Reset reads and a step quantity of 100 Set reads, which are used as ordinates of a space. 100Reset means performing the reading operation on a high resistance of the unit for 100 times; 100Set means performing the reading operation on a low resistance of the unit for 100 times. According to characteristics of resistance distribution after the unit operation, the diagram may be divided into 8 categories as abscissa. Finally, the whole observed space may correspond to the four states of the chip.

In some embodiments of the present disclosure, after predicting the endurance of the target chip through the machine learning model, the method may further include: testing the machine learning model according to the test set.

In some embodiments of the present disclosure, after completing the endurance prediction for the target chip, it is necessary to verify a prediction success rate of the machine learning model. Therefore, the prediction success rate of the machine learning model may be verified by using the test set in the data set.

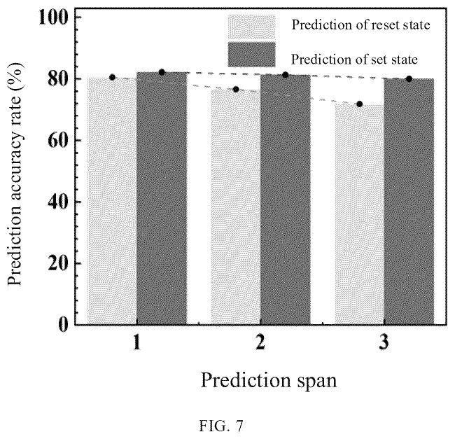

For example, please refer to FIG. 6. FIG. 6 shows a schematic diagram of a model training result according to some embodiments of the present disclosure. As shown in FIG. 6, a model parameter of the machine learning model may be trained more accurately with an increase of the observation sequence (label) in the training set, and an accuracy rate of the machine learning model after the training may reach 83.6%.

For another example, please refer to FIG. 7. FIG. 7 shows a schematic diagram of a model prediction result according to some embodiments of the present disclosure. As shown in FIG. 7, the trained machine learning model is tested, and the prediction result is compared with the test set, and the highest prediction accuracy rate may reach 82.2%. With a gradual increase of the prediction span, the accuracy rate gradually decreases. The maximum prediction span may reach 3. That is, a failure state of the next 1500 periods may be predicted.

In some embodiments of the present disclosure, after predicting the endurance of the target chip through the machine learning model, the method may further include: repairing the target chip by adjusting an operating voltage according to the prediction result.

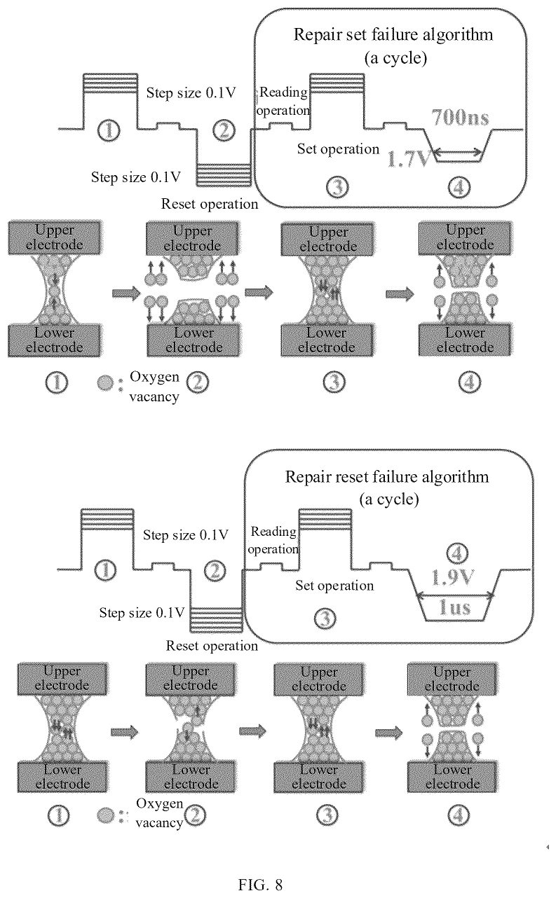

Please refer to FIG. 8. FIG. 8 shows a schematic diagram of a step-by-step repair algorithm according to some embodiments of the present disclosure. According to the prediction result, a memory array may be repaired by using the step-by-step repair algorithm. Specifically, when the chip is predicted as a set fail, a reset pulse programmed by a traditional incremental stepping pulse may be changed into a small 700 ns/1.6V reset single pulse, and combined with a set pulse programmed by a normal incremental stepping pulse. The set fail means that an excessive reset pulse causes an oxygen vacancy (Vo) to move away from a switch interface, leading to a depletion of the oxygen vacancy at an interface. By applying the improved algorithm, the oxygen vacancy may gradually return to an equilibrium state under such a large set pulse.

In addition, when an excessively strong set pulse is applied to the target chip, the reset fail may occur. A traditional method of simply increasing the reset voltage (even DC reset operation) may produce a very steep potential gradient at two ends of a contraction of a hourglass conductive filament, which may make the conductive filament very unstable. A structure of the conductive filament may be easily affected by vacancy generation or movement, which may accelerate a failure of endurance. Therefore, a reset single pulse with an amplitude slightly greater than an average reset voltage and an increased pulse width of 1.9 V/1 us may be combined with an incremental step pulse programming set pulse. The reset pulse may inhibit an excessive drift of the oxygen vacancy caused by the set operation, which may achieve a redistribution of the oxygen vacancy in a switching layer and gradually return to an initial equilibrium state.

In the above-mentioned embodiments, the above-mentioned programming algorithm may avoid applying an excessive programming energy to the chip and causing a damage to the chip. A level of the chip may be slowly restore to a normal level by using the step-by-step programming algorithm, which may effectively improve a service life of the chip. In the process of applying an optimization algorithm, it is generally enough to repeat the operation for 10 times.

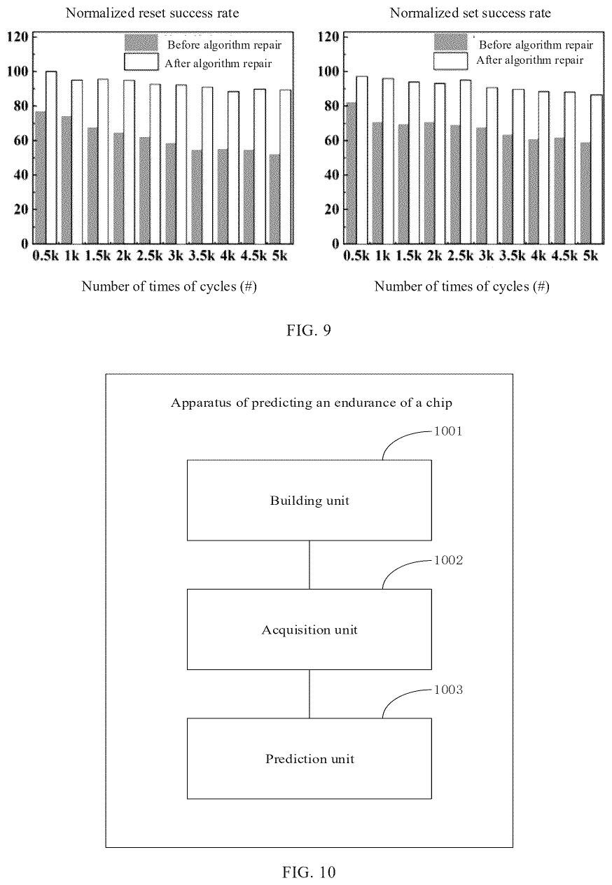

Next, please refer to FIG. 9. FIG. 9 shows a schematic diagram of an optimization result of a step-by-step repair algorithm according to some embodiments of the present disclosure. Through an optimization of a new programming algorithm, success rates of set and reset under different cycles are acquired. A solid column indicates a success rate of the memory array only when applying an incremental step pulse programming; a hollow column indicates a success rate when applying the step-by-step repair algorithm after using the established machine learning model to predict the memory array. The success rates may be increased by an average of 15% to 20%.

Next, some apparatus embodiments of the present disclosure will be described with reference to the accompanying drawings. Please refer to FIG. 10. FIG. 10 shows a block diagram of an apparatus of predicting an endurance of a chip according to some embodiments of the present disclosure. An apparatus 1000 may include a building unit 1001, an acquisition unit 1002, and a prediction unit 1003.

The building unit 1001 may be used to build a dataset according to endurance test data of a target chip, and the target chip includes a training set and a test set; the acquisition unit 1002 may be used to acquire a machine learning model and train the machine learning model through the training set; the prediction unit 1003 may be used to predict an endurance of the target chip through the machine learning model. The machine learning model includes a state transition matrix, an observed-state probability matrix and a hidden-state initial probability distribution, the state transition matrix is configured to characterize a probability that the target chip jumps to each hidden state when the target chip is in a certain hidden state, and the observed-state probability matrix is configured to characterize a probability of an occurrence of each observed state when the target chip is in a certain hidden state.

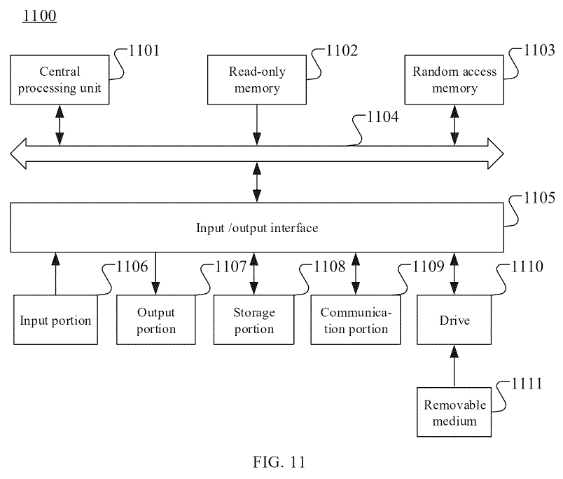

FIG. 11 shows a schematic structural diagram of a computer system of an electronic device according to some embodiments of the present disclosure. It should be noted that a computer system 1100 of the electronic device shown in FIG. 11 is only an example, and should not bring any limitation to the function and application scope of the embodiments of the present disclosure.

As shown in FIG. 11, the computer system 1100 includes a Central Processing Unit (CPU) 1101, which may perform various appropriate actions and processes according to a program stored in a Read-Only Memory (ROM) 1102 or a program loaded from a storage portion 1108 into a Random Access Memory (RAM) 1103. For example, the method in the above-mentioned embodiments may be performed. In the RAM 1103, various programs and data required for a system operation are also stored. The CPU 1101, the ROM 1102 and the RAM 1103 are connected to each other through a bus 1104. An Input/Output (I/O) interface 1105 is also connected to the bus 1104.

The following components are connected to the I/O interface 1105: an input portion 1106 including a keyboard, a mouse, etc.; an output portion 1107 such as a Cathode Ray Tube (CRT), a Liquid Crystal Display (LCD), etc., and a loudspeaker, etc., the storage portion 1108 including a hard disk, etc.; and a communication portion 1109 including a network interface card such as a LAN (Local Area Network) card, a modem, etc. The communication portion 1109 performs communication processing via a network such as the Internet. A drive 1110 is also connected to the I/O interface 1105 as required. A removable medium 1111, such as a magnetic disk, an optical disk, a magneto-optical disk, a semiconductor memory, etc., is installed on the drive 1110 as required, so that a computer program read therefrom may be installed into the storage portion 1108 as required.

In particular, according to the embodiments of the present disclosure, the process described above with reference to the flowchart may be implemented as a computer software program. For example, the embodiments of the present disclosure provide a computer program product, which includes a computer program carried on a computer-readable medium, and the computer program contains a program code for performing the method shown in the flowchart. In such an embodiment, the computer program may be downloaded and installed from the network through the communication portion 1109 and/or installed from the removable medium 1111. When the computer program is executed by the central processing unit (CPU) 1101, various functions defined in the system of the present disclosure may be performed.

It should be noted that the computer-readable medium shown in the embodiments of the present disclosure may be a computer-readable signal medium or a computer-readable storage medium or any combination of the two. The computer-readable storage medium may be, for example, but not limited to, an electrical, magnetic, optical, electromagnetic, infrared, or semiconductor system, apparatus or chip, or any combination of the above. More specific examples of the computer-readable storage medium may include, but are not limited to, an electrical connection with one or more wires, a portable computer diskette, a hard disk, a Random Access Memory (RAM), a Read-Only Memory (ROM), an Erasable Programmable Read-Only Memory (EPROM), a flash memory, an optical fiber, a Compact Disc Read-Only Memory (CD-ROM), an optical memory chip, a magnetic memory chip, or any suitable combination of the above. In the present disclosure, the computer-readable storage medium may be any tangible medium containing or storing a program, and the program may be used by or in combination with an instruction execution system, apparatus or chip. In the present disclosure, a computer-readable signal medium may include a data signal propagated in a baseband or as a part of a carrier wave, in which a computer-readable program code is carried. The propagated data signal may take various forms, including but not limited to an electromagnetic signal, an optical signal or any suitable combination of the above. The computer-readable signal medium may also be any computer-readable medium other than the computer-readable storage medium, and the computer-readable medium may send, propagate or transmit the program for use by or in combination with the instruction execution system, apparatus or chip. The program code contained in the computer-readable medium may be transmitted by any suitable medium, including but not limited to: wireless, wired, etc., or any suitable combination of the above.

The flowcharts and block diagrams in the accompanying drawings illustrate possibly implemented architectures, functions and operations of the systems, methods and computer program products according to various embodiments of the present disclosure. Each block in the flowchart or block diagram may represent a module, a program segment, or a part of code, and the above-mentioned module, program segment, or the part of code contains one or more executable instructions for achieving specified logical functions. It should also be noted that in some alternative implementations, the functions marked in the blocks may occur in a different order than those marked in the accompanying drawings. For example, two blocks shown in succession may actually be executed substantially in parallel, and they may sometimes be executed in a reverse order, depending on the functions involved. It should also be noted that each block in the block diagram achieved by a dedicated hardware-based system that executes specified functions or operations, or may be achieved by a combination of a dedicated hardware and a computer instruction.

The units described in the embodiments of the present disclosure may be achieved by software or hardware, and the described units may also be provided in a processor. The names of these units do not constitute a limitation of the units themselves in some cases.

On the other hand, some embodiments of the present disclosure further provide a computer program product or computer program, the computer program product or computer program includes a computer instruction, and the computer instruction is stored in the computer-readable storage medium. A processor of a computer device reads the computer instruction from the computer-readable storage medium, and the processor executes the computer instruction, so that the computer device executes the method of predicting an endurance of a chip described in the above-mentioned embodiments.

On the other hand, some embodiments of the present disclosure further provide a computer-readable medium. The computer-readable medium may be included in the electronic device described in the above-mentioned embodiments; or it may exist alone without being assembled into the electronic device. The above-mentioned computer-readable medium carries one or more programs which, when executed by an electronic device, cause the electronic device to implement the method of predicting an endurance of a chip described in the above-mentioned embodiments.

It should be noted that although several modules or units of a device for action execution are mentioned in the above-mentioned detailed descriptions, the division is not mandatory. In fact, according to the embodiments of the present disclosure, the features and functions of two or more modules or units described above may be embodied in a module or unit. On the contrary, the features and functions of a module or unit described above may be further divided to be embodied by a plurality of modules or units.

From the descriptions of the above-mentioned embodiments, it is easy for those ordinary skilled in the art to understand that the exemplary embodiments described here may be achieved by software or by combining software with necessary hardware. Therefore, some embodiments according to the present disclosure may be embodied in a form of a software product, and the software product may be stored in a non-volatile storage medium (which may be a CD-ROM, a USB flash drive, a mobile hard disk, etc.) or on a network, and includes several instructions to make a computing device (which may be a personal computer, a server, a touch terminal, or a network device, etc.) execute the method according to the embodiments of the present disclosure.

In the technical solutions provided by some embodiments of the present disclosure, the dataset is built according to the endurance test data of the target chip, and the dataset includes the training set and the test set, then the machine learning model is trained through the training set, and finally the endurance of the target chip is predicted through the machine learning model. In the technical solutions provided by the present disclosure, the state of the non-volatile memory chip in a certain prediction span in the future may be predicted by training the machine learning model and then predicting the endurance through the machine learning model, so as to perform a repairment in advance in a targeted manner, and finally improve a service life of the non-volatile memory chip.

Those ordinary skilled in the art may easily think of other embodiments of the present disclosure after considering the specification and practicing the embodiments disclosed herein. The present disclosure is intended to cover any variations, uses or adaptations of the present disclosure, and these variations, uses or adaptations follow the general principle of the present disclosure and include common sense or common technical means in the technical art that are not disclosed in the present disclosure. It should be understood that the present disclosure is not limited to the precise structure described above and shown in the accompanying drawings, and various modifications and changes may be made without departing from its scope. The scope of the present disclosure is limited only by the appended claims.

1. A method of predicting an endurance of a chip, comprising:
building a dataset according to endurance test data of a target chip, wherein the dataset comprises a training set and a test set;
acquiring a machine learning model, and training the machine learning model through the training set; and
predicting an endurance of the target chip through the machine learning model;
wherein the machine learning model comprises a state transition matrix, an observed-state probability matrix, and a hidden-state initial probability distribution, wherein the state transition matrix is configured to characterize a probability that the target chip jumps to each hidden state when the target chip is in a certain hidden state, and the observed-state probability matrix is configured to characterize a probability of an occurrence of each observed state when the target chip is in a certain hidden state.

2. The method according to claim 1, wherein the building a dataset according to endurance test data of a target chip comprises: acquiring the endurance test data of the target chip for at least one working period, and building the dataset based on the endurance test data of each period.

3. The method according to claim 2, wherein the acquiring the endurance test data of the target chip for at least one working period comprises: in a working period, performing a single-pulse operation on the target chip for a first predetermined number of times, and performing a cyclic pulse operation on the target chip for a second predetermined number of times, so as to simulate a normal working process of the target chip; and respectively performing a reading operation on high and low resistance states of the target chip for a third predetermined number of times, so as to acquire operating voltage data, resistance values corresponding to the high and low resistance states, and a reading operation state parameter as the endurance test data.

4. The method according to claim 3, wherein the training the machine learning model through the training set comprises: determining the operating voltage data, the resistance values corresponding to the high and low resistance states, and the reading operation state parameter in the training set as the endurance test data as an input, training the machine learning model by using a Baum-Welch algorithm, so as to determine the state transition matrix, the observed-state probability matrix, and the hidden-state initial probability distribution.

5. The method according to claim 1, after predicting the endurance of the target chip through the machine learning model, the method further comprises: testing the machine learning model according to the test set.

6. The method according to claim 1, after predicting the endurance of the target chip through the machine learning model, the method further comprises: repairing the target chip by adjusting an operating voltage according to a prediction result.

7. An apparatus of predicting an endurance of a chip, comprising:
a building unit configured to build a dataset according to endurance test data of a target chip, wherein the dataset comprises a training set and a test set;
an acquisition unit configured to acquire a machine learning model and train the machine learning model through the training set; and
a prediction unit configured to predict an endurance of the target chip through the machine learning model;
wherein the machine learning model comprises a state transition matrix, an observed-state probability matrix and a hidden-state initial probability distribution, the state transition matrix is configured to characterize a probability that the target chip jumps to each hidden state when the target chip is in a certain hidden state, and the observed-state probability matrix is configured to characterize a probability of an occurrence of each observed state when the target chip is in a certain hidden state.

8. A computer-readable storage medium, wherein the computer-readable storage medium stores at least one program code, and the at least one program code is loaded and executed by a processor to implement steps of the method of predicting an endurance of a chip according to claim 1.

9. An electronic device, comprising a memory and a processor, wherein the memory stores a computer program which, when executed by the processor, causes the processor to perform steps of the method of predicting an endurance of a chip according to claim 1.
